(19) United States
(12) Patent Application Publication
(10) Pub. No.: US 2015/0129900 A1
(43) Pub. Date: May 14, 2015

(54) LIGHT EMITTING DIODE STRUCTURE

(71) Applicant: Lextar Electronics Corporation, Hsinchu (TW)

(72) Inventors: Shih-Pu YANG, Kaohsiung City (TW); Po-Hung TSOU, New Taipei City (TW)

(21) Appl. No.: 14/327,667

(22) Filed: Jul. 10, 2014

(30) Foreign Application Priority Data
Nov. 11, 2013 (TW) 102140910

(51) Int. Cl. H01L 33/60

(52) U.S. Cl. CPC H01L 33/60
USPC 257/88; 257/98

(57) ABSTRACT

A light emitting diode structure includes a patterned substrate, a light emitting diode die, and a first reflector. The light emitting diode die is disposed on the patterned substrate and emitting a light in wavelength λ. The first reflector is formed over the patterned substrate, covering the patterned substrate which is not covered by the light emitting diode die, to reflect the light emitted from the light emitting diode die. Also, plurality of light emitting diode die can be connected in series to form a high voltage light emitting diode structure.

### RELATED APPLICATIONS

This application claims priority to Taiwan Application Serial Number 102140910, filed Nov. 11, 2013, which is herein incorporated by reference.

### BACKGROUND

1. Field of Invention

The present invention relates to a light emitting diode structure. More particularly, the present invention relates to a high voltage light emitting diode structure.

2. Description of Related Art

As the light emitting diode (LED) technology progress, the demand of the LED on the market turns toward larger power and much brightness. High voltage light emitting diode (HVLED) is therefore formed by connecting LED dies, which is divided from a wafer, in series, to increase power of the LED. The HVLED may determine how many LED dies need to be connected for the demand of different input voltage. Also, the multiple LED dies and low current design of the HVLED may diffuse the current uniformly and enhance the light extraction efficiency. The HVLED can also apply in an alternating current environment by connecting with a bridge rectifier.

However, because the HVLED is formed by connecting LED dies, which is divided from the wafer surface, in series. The LED dies are separated by the trenches, but the light comes out from the sidewall of the LED die also dissipate through the trenches, making the light can not be efficiently extracted. The scattering light between the dies is absorbed and form heat energy, which affects the efficiency of the HVLED.

### SUMMARY

Therefore, the present invention provides a light emitting diode structure which extracts the light comes out from the sidewall of the LED dies by coating a reflector on a patterned substrate to enhance the light extraction rate of the HV LED.

One aspect of the present invention is a light emitting diode structure, including a patterned substrate; a light emitting diode die disposed on the patterned substrate and emitting a light in wavelength λ; and a first reflector formed over the patterned substrate, covering the patterned substrate which is not covered by the light emitting diode die, to reflect the light emitted from the light emitting diode die.

Another aspect of the present invention is a light emitting diode structure, including a patterned substrate; a plurality of light emitting diode dies, disposed separately on the patterned substrate, and emitting light in wavelength λ; a plurality of conductors, electrically connecting the light emitting dies; and a second reflector, formed over the patterned substrate, which is not covered by the light emitting diode dies and the conductors, to reflect the light emitted from the light emitting diode dies.

According to one embodiment of the present invention, a surface shape of the first reflector is a flat surface, curved surface, continuous arc surface, serrated surface, trapezoid surface, or a surface shape the same with a surface shape of the patterned substrate.

According to one embodiment of the present invention, a surface shape of the second reflector is flat surface, curved surface, continuous arc surface, serrated surface, trapezoid surface, or a surface shape the same with a surface shape of the patterned substrate.

According to one embodiment of the present invention, the first reflector is a distributed bragg reflector (DBR), omni-directional reflector (ODR), or metal reflector.

According to one embodiment of the present invention, the second reflector is a distributed bragg reflector (DBR), omni-directional reflector (ODR), or metal reflector.

According to one embodiment of the present invention, the DBR includes a first dielectric layer and a second dielectric layer staggered stacked, a refractivity of the first dielectric layer is larger than that of the second dielectric layer, and the first dielectric layer contacts the patterned substrate.

According to one embodiment of the present invention, the ODR includes a low refractivity material layer and a metal layer having multiple refractivities, wherein the low refractivity material layer comprising a dielectric material having thickness with λ/4.

According to one embodiment of the present invention, the metal reflector includes a material selected from silver, aluminum or combinations thereof.

According to one embodiment of the present invention, the patterned substrate is a patterned sapphire substrate.

According to one embodiment of the present invention, the conductor comprises a material selected from a group consisting of gold, silver, copper, nickel, tin, aluminum and combinations thereof.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross sectional view of a light emitting diode structure according to various embodiments of the present invention;

FIGS. 2A-2E are cross sectional views of a light emitting diode structure according to various embodiments of the present invention;

FIG. 3 is a cross sectional view of a light emitting diode structure according to various embodiments of the present invention;

FIG. 4 is a cross sectional view of a light emitting diode structure according to various embodiments of the present invention;

FIG. 5 is a top view of a light emitting diode structure according to various embodiments of the present invention; and

FIG. 6 is a top view of a light emitting diode structure according to various embodiments of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

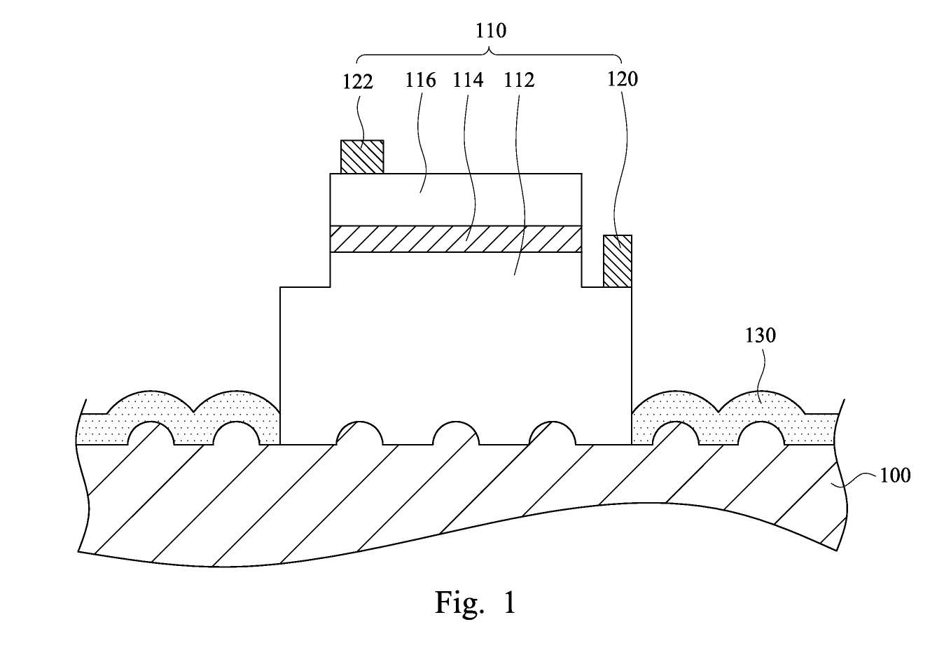

Referring to FIG. 1, FIG. 1 is a cross sectional view of a light emitting diode structure according to various embodiments of the present invention. The light emitting diode structure includes a patterned substrate 100, a light emitting diode die 110, and a first reflector 130. The light emitting diode die 110 is disposed on the patterned substrate 100 and emitting a light in wavelength λ. The first reflector 130 is formed over the patterned substrate 100, covering the patterned substrate 100 which is not covered by the light emitting diode die, to reflect the light emitted from the light emitting diode die 110. According to one embodiment of the present invention, the patterned substrate is a patterned sapphire substrate or an aluminum nitride substrate. According to one embodiment of the present invention, the first reflector 130 is a distributed bragg reflector (DBR), omni-directional reflector (ODR), or metal reflector. Wherein the metal reflector includes a material selected from silver, aluminum or combinations thereof. A surface shape of the first reflector 130 is the same with a surface shape of the patterned substrate 100.

According to one embodiment of the present invention, the light emitting diode die 110 includes a first semiconductor layer 112, a light emitting layer 114, a second semiconductor layer 116, a first electrode 120 and a second electrode 122. Wherein, the first semiconductor layer 112 is formed over the patterned substrate 100. The light emitting layer 114 is formed over the first semiconductor layer 112. The second semiconductor 116 is formed over the light emitting layer 114. The first electrode 120 is formed over the first semiconductor layer 112, and electrically connects with the first semiconductor layer 112. The second electrode 122 is formed over the second semiconductor layer 116, and electrically connects with the second semiconductor layer 116. The first semiconductor layer 112 and the second semiconductor layer 116 can be different type of doped semiconductor material. For example, the material of the first semiconductor layer 112 may be n-type semiconductor material, and the second semiconductor layer 116 may be p-type semiconductor material, which may interchange. The light emitting layer 114 may include a multiple quantum well (MQW) structure formed by semiconductor materials. The first and second electrode 120,122 may be a multiple transparent conductive layer that has high refractivity or is metal.

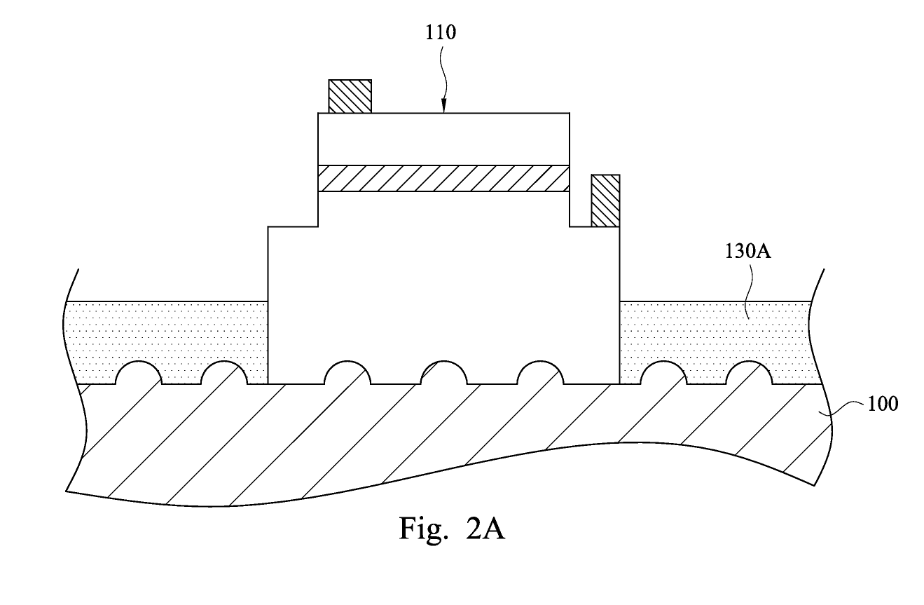

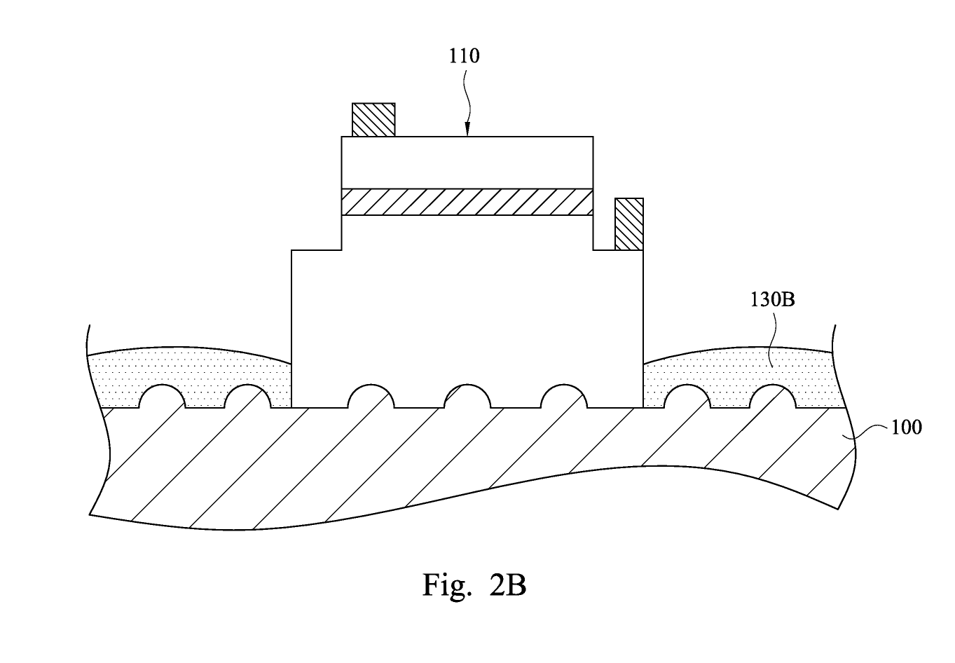

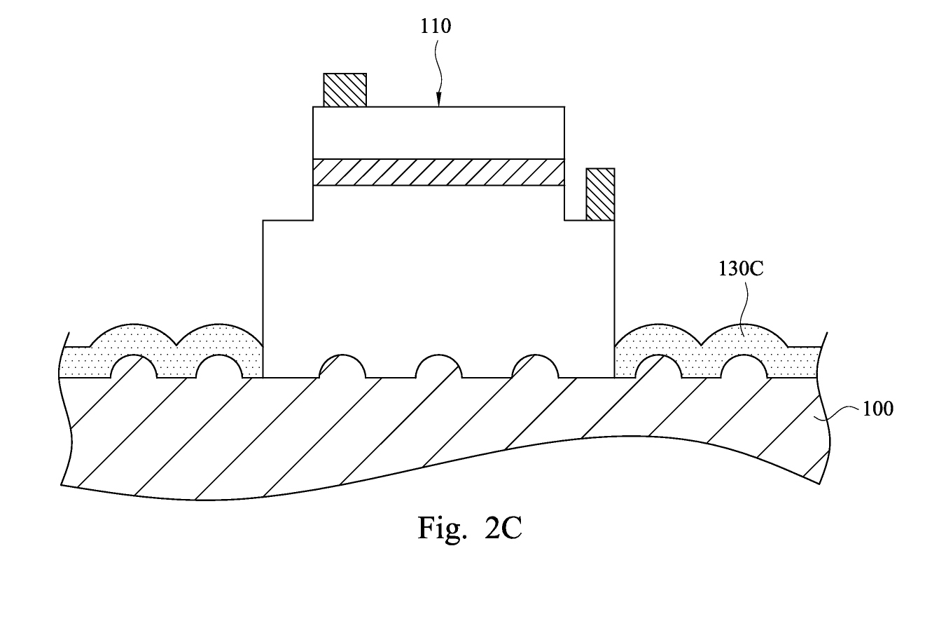

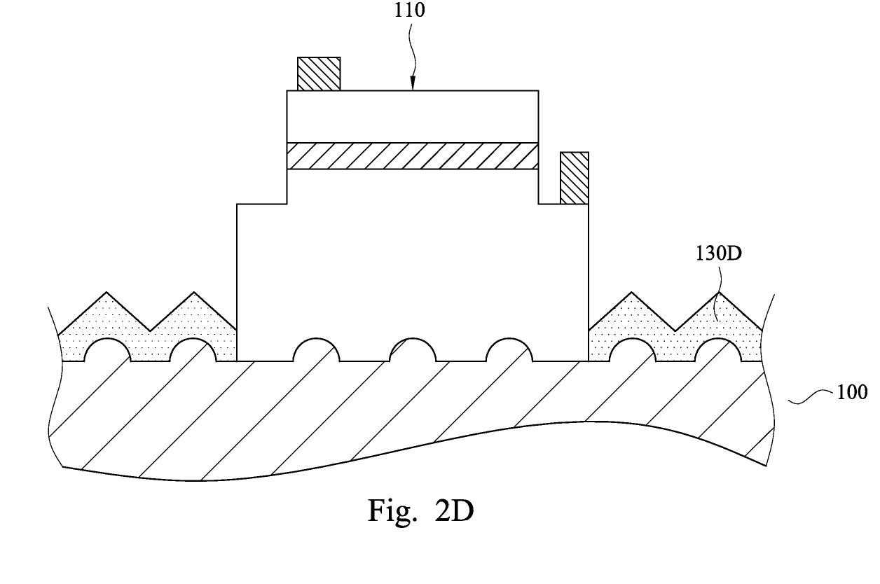

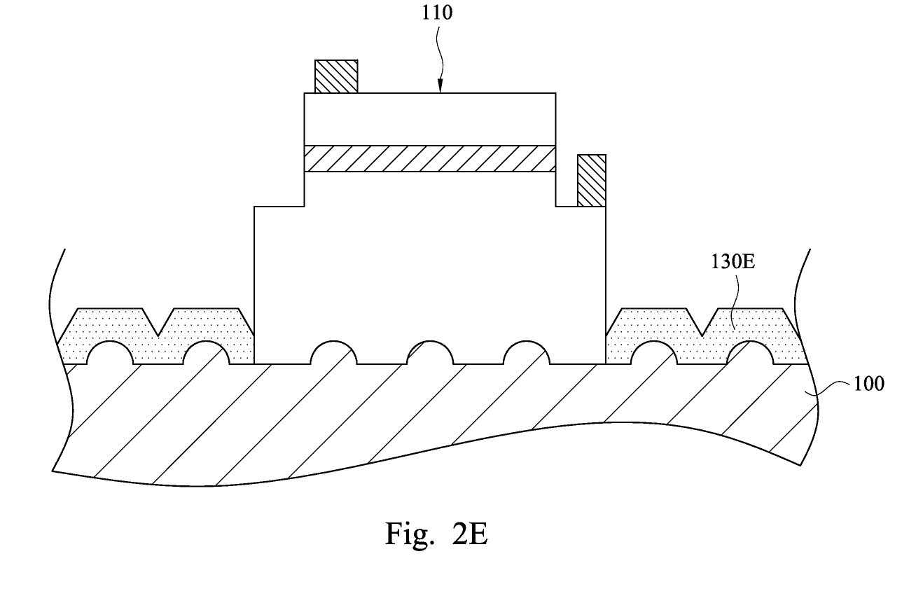

Referring to FIGS. 2A-2E, FIGS. 2A-2E are cross sectional views of a light emitting diode structure according to various embodiments of the present invention, which disclose the reflector structure having different surface shape. Referring to FIG. 2A, a light emitting diode die 110 is disposed on a patterned substrate 100. A first reflector 130A is formed over the patterned substrate 100, covering the patterned substrate 100 which is not covered by the light emitting diode die 110. A surface shape of the first reflector 130A is a flat surface.

Referring to FIGS. 2B-2E, the depicted structure is similar with FIG. 2A, but the only difference is the surface shape of the first reflectors 130B, 130C, 130D, 130E. In the embodiment shown in FIG. 2B, the surface shape of the first reflector 130B is a continuous arc surface. In FIG. 2C, the surface shape of the first reflector 130C is a curved surface. In FIG. 2D, the surface shape of the first reflector 130D is a serrated surface. In FIG. 2E, the surface shape of the first reflector 130E is a trapezoid surface. From the above-mentioned embodiments, the surface shape of the reflector may be different from the surface shape of the patterned substrate such as a flat surface, curved surface, continuous arc surface, serrated surface, trapezoid surface, or a surface shape the same with the surface shape of the patterned substrate.

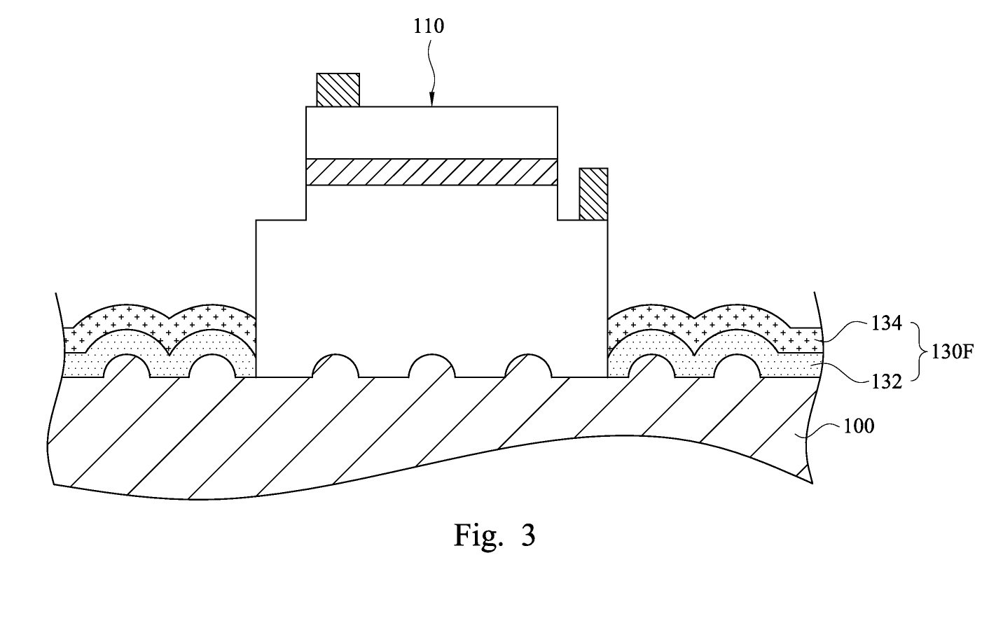

Referring to FIG. 3, FIG. 3 is a cross sectional view of a light emitting diode structure according to various embodiments of the present invention. Wherein a light emitting diode die 110 disposed on a patterned substrate 100. A first reflector 130F is formed over the patterned substrate 100, covering the patterned substrate 100 which is not covered by the light emitting diode die 110. Wherein the first reflector 130F is a stacked structure including at least two layers with different materials. As shown in FIG. 3, according to various embodiments of the present invention, the first reflector 130F includes a first material layer 132 formed over the patterned substrate 100, and a second material layer 134 formed over the first material layer 132, in which the first material layer 132 has different materials with the second material layer 134.

In some embodiments of the present invention, the first reflector 130F is a distributed bragg reflector (DBR), the first material layer 132 is a first dielectric layer, and the second material layer 134 is a second dielectric layer. The DBR includes the first dielectric layer and the second dielectric layer staggered stacked, wherein a refractivity of the first dielectric layer is larger than that of the second dielectric layer, and the first dielectric layer contacts the patterned substrate. A material of the first and second dielectric layers is selected form silicon, silicon dioxide, silicon nitride, titanium dioxide, gallium arsenate, AlGaAs, AlGaInP, AlInP or combinations thereof. A plurality of DBRs may be stacked to reach the desired reflectivity (which is not shown in the figure).

In some embodiments of the present invention, the first reflector 130F is an omni-directional reflector (ODR). The first material layer 132 is a metal layer having multiple refractivities, and the second material layer 134 is a low refractivity material layer, wherein the thickness of the low refractivity material layer is λ/4. The low refractivity material is a dielectric material such as silicon dioxide. A material of the metal layer having multiple refractivities is selected form silver, copper, aluminum or combinations thereof.

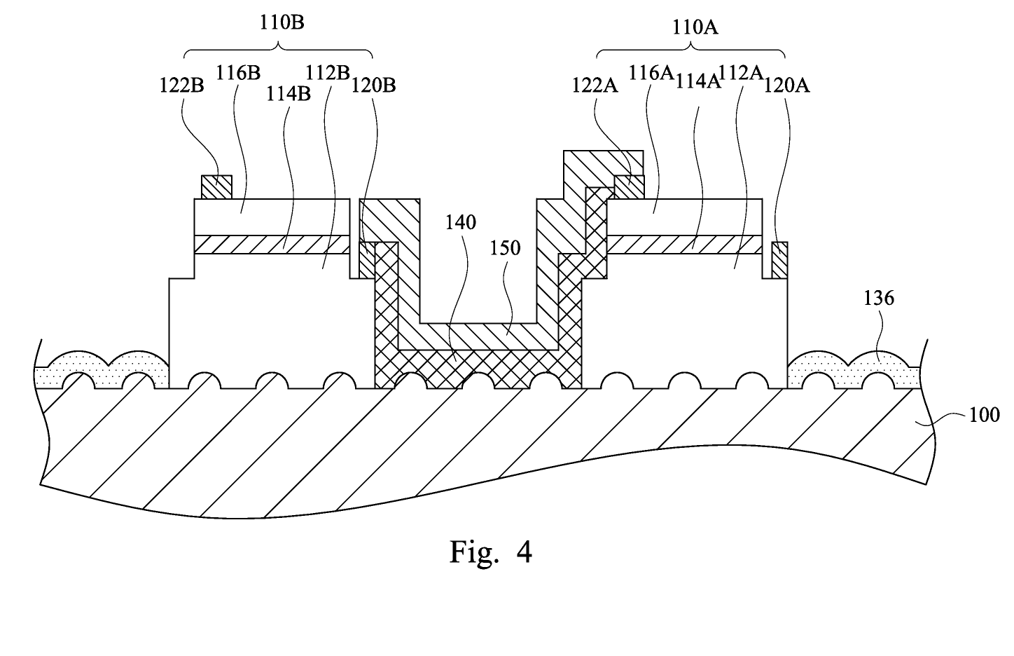

Referring to FIG. 4, FIG. 4 is a cross sectional view of a light emitting diode structure according to various embodiments of the present invention. The embodiment is of another aspect of the present disclosure. Which includes a patterned substrate 100, a plurality of light emitting diode dies 110, a plurality of conductors 150, and a second reflector 136. In various embodiments of the present invention, the patterned substrate 100 is a patterned sapphire substrate or an aluminum nitride substrate. The light emitting diode dies 110 are disposed separately on the patterned substrate 100, and emit light in wavelength λ. The conductors 150 are electrically connected to the light emitting diode dies 110. A material of the conductor 150 is selected from a group consisting of gold, silver, copper, nickel, tin, aluminum and combinations thereof. In some embodiments, an insulation layer 140 is disposed between the conductors 150 and the patterned substrate 100, and the light emitting dies 110 and the patterned substrate 100. For example, a material of the insulation layer 140 is silicon dioxide. The second reflector 136 is formed over the patterned substrate 100, covering the patterned substrate 100 which is not covered by the light emitting diode dies 110 and the conductors 150, to reflect the light emitted from the light emitting diode dies 110.

In various embodiments, the second reflector 136 has all the qualities the same with the first reflector 130. For example, the surface shape of the second reflector 136 may be a flat surface, curved surface, continuous arc surface, serrated surface, trapezoid surface, or a surface shape the same with the surface shape of the patterned substrate. The shape of the reflector may design by the patterning and lithography process. The second reflector 136 may be a distributed bragg reflector (DBR), omni-directional reflector (ODR), or metal reflector. The DBR includes the first dielectric layer and the second dielectric layer staggered stacked, wherein a refractivity of the first dielectric layer is larger than that of the second dielectric layer, and the first dielectric layer contacts the patterned substrate. The ODR includes a metal layer having multiple refractivities and a low refractivity material layer, which includes dielectric material and the thickness of which is λ/4. A material of the metal layer having multiple refractivities is selected form silver, copper, aluminum or combinations thereof.

In various embodiments of the present invention, the light emitting diode die 110 includes a first semiconductor layer 112, a light emitting layer 114, a second semiconductor layer 116, a first electrode 120 and a second electrode 122. Wherein, the first semiconductor layer 112 is formed over the patterned substrate 100. The light emitting layer 114 is formed over the first semiconductor layer 112. The second semiconductor 116 is formed over the light emitting layer 114. The first electrode 120 is formed over the first semiconductor layer 112, and electrically connects with the first semiconductor layer 112. The second electrode 122 is formed over the second semiconductor layer 116, and electrically connects with the second semiconductor layer 116. The first semiconductor layer 112 and the second semiconductor layer 116 can be different type of doped semiconductor material. For example, the material of the first semiconductor layer 112 may be n-type semiconductor material, and the second semiconductor layer 116 may be p-type semiconductor material, which may interchange. The light emitting layer 114 may include a multiple quantum well (MQW) structure formed by semiconductor materials. The first and second electrode 120,122 may be a multiple transparent conductive layer that has high refractivity or is metal, such as gold, silver, copper, or aluminum.

A high voltage light emitting diode die (HV LED) may be formed by connecting a plurality of light emitting diode dies 110 in series. Particularly, in FIG. 4, the plurality of light emitting diode dies 100 are two light emitting dies 110A, 1108 disposed on the patterned substrate 100 separately. The two light emitting diode dies 110A, 1108 are connected by a conductor 150 which electrically connects the second electrode 122A of the light emitting die 110A with the first electrode 1208 of the light emitting die 1108. An insulation layer 140 is under the conductor 150 to protect the conductor 150. The second reflector 136 is plated on the patterned substrate, covering the patterned substrate which has no conductor 150 and no light emitting diode dies 110A, 1108 to reflect the light emitted form the light emitting diode dies 110A, 1108, therefore to enhance the light extraction rate of the HV LED.

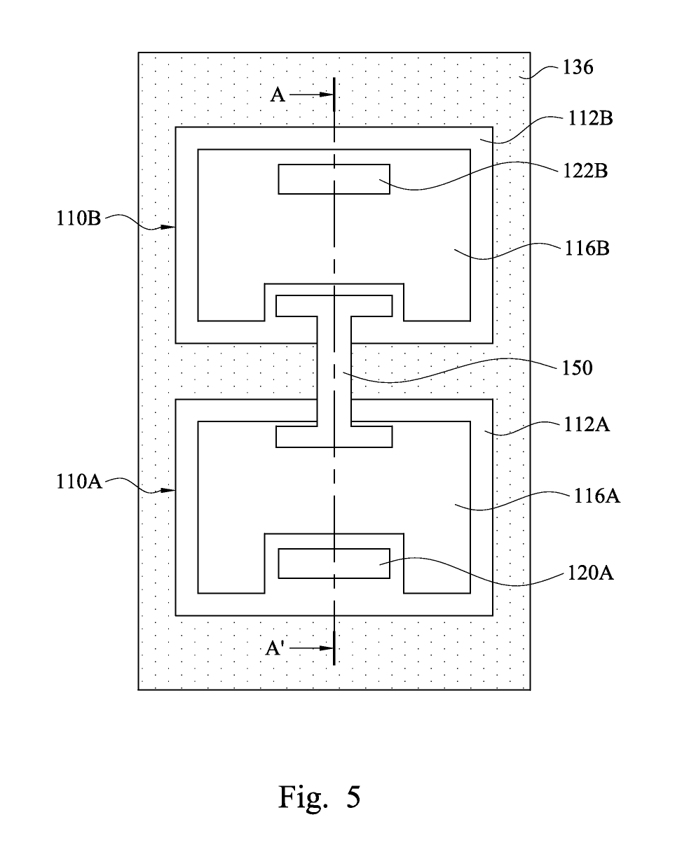

FIG. 5 is a top view of a light emitting diode structure according to various embodiments of the present invention, which is referred to, or together with FIG. 4, for clearly understanding the present disclosure. FIG. 4 is the cross-sectional view of the AA′ line in FIG. 5. As shown in FIG. 5, two light emitting diode dies 110A, 1108 separately disposed on the patterned substrate with a distance, and are electrically connected by a conductor 150. Part of the first semiconductor layer 112A, 1128, second semiconductor layer 116A, 1168, and the first electrode 120A and the second electrode 122B are shown in the top view figure. A second reflector 136 is formed over the patterned substrate, covering the patterned substrate which has no light emitting diode die 110 and conductor 150.

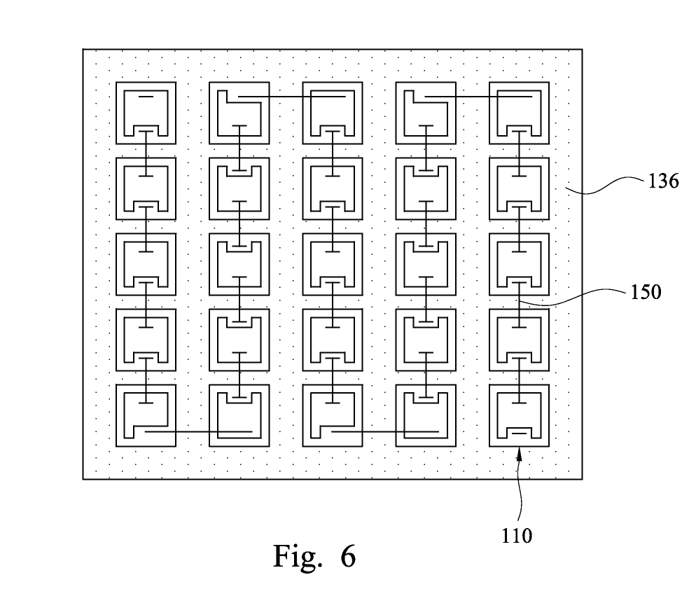

Referring to FIG. 6, in various embodiments of the present disclosure, the plurality of light emitting diode dies are not limited for only two light emitting diode dies. A HV LED structure may be formed by connecting various of light emitting diode dies 110 in series for the voltage and light emitting efficiency demand. FIG. 6 is a top view of a light emitting diode structure according to various embodiments of the present invention. The top view of the light emitting diode structure shows how the plurality of light emitting diode dies connected in series clearly. As shown in the figure, the plurality of light emitting diode dies 110 are disposed separately on a patterned substrate, and the light emitting diode dies 110 are electrically connected by the conductors 150. The patterned substrate which is not covered by the light emitting diode dies 110 and the conductors 150 are plated a second reflector 136. The second reflector 136 covers an area between the light emitting diode dies 110 in the HV LED, and the peripheral part of the HV LED where has the light emitting diode dies on only one side to enhance the light extraction efficiency of the HV LED. The amount of the light emitting diode dies 110 may adjust by the demand of the electricity supply. And a plurality of different HV LEDs may be formed on the different area of one wafer.

According to the above-mentioned embodiments, the present invention provides the light emitting diode structure, which is the HV LED structure having one or more light emitting diode dies. By plating the reflector on the patterned substrate to reflect the light emitted from the light emitting diode dies, the light extraction efficiency can be enhanced. Also, the heat residual formed by the light emitted form the light emitting diode dies can be decreased. And the lifetime of the light emitting diode structure can be prolonged.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode structure, comprising:
a patterned substrate;
a light emitting diode die disposed on the patterned substrate and emitting a light in wavelength λ; and
a first reflector formed over the patterned substrate, covering the patterned substrate which is not covered by the light emitting diode die, to reflect the light emitted from the light emitting diode die.

2. The light emitting diode structure of claim 1, wherein a surface shape of the first reflector is flat surface, curved surface, continuous arc surface, serrated surface, trapezoid surface, or a surface shape the same with a surface shape of the patterned substrate.

3. The light emitting diode structure of claim 1, wherein the first reflector is a distributed bragg reflector (DBR), omni-directional reflector (ODR), or metal reflector.

4. The light emitting diode structure of claim 3, wherein the DBR comprises a first dielectric layer and a second dielectric layer staggered stacked, wherein a refractivity of the first dielectric layer is larger than that of the second dielectric layer, and the first dielectric layer contacts the patterned substrate.

5. The light emitting diode structure of claim 3, wherein the ODR comprises a low refractivity material layer and a metal layer having multiple refractivities, wherein the low refractivity material layer comprising a dielectric material having thickness with 80 /4.

6. The light emitting diode structure of claim 3, wherein the metal reflector comprises a material selected from silver, aluminum or combinations thereof.

7. The light emitting diode structure of claim 1, wherein the patterned substrate is a patterned sapphire substrate.

8. A light emitting diode structure, comprising:
a patterned substrate;
a plurality of light emitting diode die, disposed separately on the patterned substrate, and emitting light in wavelength λ;
a plurality of conductors, electrically connecting the light emitting diode dies; and
a second reflector, formed over the patterned substrate, which is not covered by the light emitting diode dies and the conductors, to reflect the light emitted from the light emitting diode dies.

9. The light emitting diode structure of claim 8, wherein a surface shape of the second reflector is a flat surface, curved surface, continuous arc surface, serrated surface, trapezoid surface, or a surface shape the same with a surface shape of the patterned substrate.

10. The light emitting diode structure of claim 8, wherein the second reflector is a distributed bragg reflector (DBR), omni-directional reflector (ODR), or metal reflector.

11. The light emitting diode structure of claim 10, wherein the DBR comprises a first dielectric layer and a second dielectric layer staggered stacked, wherein a refractivity of the first dielectric layer is larger than that of the second dielectric layer, and the first dielectric layer contacts the patterned substrate.

12. The light emitting diode structure of claim 10, wherein the ODR comprises a low refractivity material layer and a metal layer having multiple refractivities, wherein the low refractivity material layer comprising a dielectric material having thickness for λ/4.

13. The light emitting diode structure of claim 10, wherein the metal reflector comprises a material selected from silver, aluminum or combinations thereof.

14. The light emitting diode structure of claim 8, wherein the conductor comprises a material selected from a group consisting of gold, silver, copper, nickel, tin, aluminum and combinations thereof.

15. The light emitting diode structure of claim 8, wherein the patterned substrate is a patterned sapphire substrate.
